(19) United States
(12) Patent Application Publication
(10) Pub. No.: US 2026/0197986 A1
(43) Pub. Date: Jul. 9, 2026

(54) SEMICONDUCTOR MEMORY DEVICE

(71) Applicant: Samsung Electronics Co., Ltd., Suwon-si (KR)

(72) Inventors: In Ho CHA, Suwon-si (KR); Min Ju KANG, Suwon-si (KR); Su Jin KANG, Suwon-si (KR); Min Soo KIM, Suwon-si (KR); Seung Hoon KIM, Suwon-si (KR); Yong Kwan KIM, Suwon-si (KR); Hui-Jung KIM, Suwon-si (KR); Hyun Jin LEE, Suwon-si (KR); Hee Jae CHAE, Suwon-si (KR)

(21) Appl. No.: 19/337,264

(22) Filed: Sep. 23, 2025

(30) Foreign Application Priority Data
Jan. 8, 2025 (KR) 10-2025-0002589

(51) Int. Cl. H10B 12/00; G11C 5/06

(52) U.S. Cl. CPC H10B 12/00; G11C 5/063; H10B 12/01

(57) ABSTRACT

A semiconductor memory device includes a substrate, a ground line on the substrate and extending in a vertical direction perpendicular to an upper surface of the substrate, a bit line on the substrate and spaced apart from the ground line in a first horizontal direction parallel to the upper surface of the substrate, wherein the bit line extends in the vertical direction, and a read word line, a read semiconductor pattern, a write semiconductor pattern, and a write word line between the ground line and the bit line and sequentially spaced apart from each other in the vertical direction, wherein a first end and a second end opposite the first end of the read semiconductor pattern are electrically connected to the ground line and the bit line, wherein an end of the write semiconductor pattern is electrically connected to the bit line.

### CROSS-REFERENCE TO RELATED APPLICATION

This application claims priority from Korean Patent Application No. 10-2025-0002589 filed on Jan. 8, 2025, in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor memory device.

### Description of Related Art

There is a need to increase integration of a semiconductor memory device in order to meet the excellent performance and low price required by consumers. In the semiconductor memory device, since integration is an important factor in determining the price of a product, an increased integration can reduce the price.

In a two-dimensional or planar semiconductor memory device, integration is mainly determined based on an area occupied by a unit memory cell, and thus is greatly affected by a level of fine pattern formation technology. However, since ultra-high-priced equipment is required for pattern miniaturization, increased integration of the semiconductor memory device may be limited. Accordingly, many studies on the integration technology of the semiconductor memory device have been conducted.

### SUMMARY

A technical benefit of the inventive concept described in the present disclosure is a semiconductor memory device with lowered process difficulty and/or improved integration.

The technical benefits of the inventive concept described in the present disclosure are not limited to the technical benefits as mentioned above, and other technical benefits not mentioned may be clearly understood by those skilled in the art from the descriptions as set forth below.

According to some embodiments of the present disclosure, a semiconductor memory device includes a substrate, a ground line on the substrate and extending in a vertical direction perpendicular to an upper surface of the substrate, a bit line on the substrate and spaced apart from the ground line in a first horizontal direction parallel to the upper surface of the substrate, wherein the bit line extends lengthwise in the vertical direction, and a read word line, a read semiconductor pattern, a write semiconductor pattern, and a write word line between the ground line and the bit line and sequentially spaced apart from each other in the vertical direction, wherein a first end of the read semiconductor pattern in the first direction is electrically connected to the bit line and a second end opposite the first end of the read semiconductor pattern is electrically connected to the ground line, wherein an end of the write semiconductor pattern in the first horizontal direction is electrically connected to the bit line.

According to some embodiments of the present disclosure, a semiconductor memory device includes a substrate, a read semiconductor pattern on the substrate and extending lengthwise in a first horizontal direction parallel to an upper surface of the substrate, a read word line between the substrate and the read semiconductor pattern and extending lengthwise in a second horizontal direction parallel to the upper surface of the substrate and intersecting the first horizontal direction, a write semiconductor pattern on the read semiconductor pattern and extending lengthwise in the first horizontal direction, a write word line on the write semiconductor pattern and extending lengthwise in the second horizontal direction, a ground line on the substrate, extending in a vertical direction perpendicular to the upper surface of the substrate and electrically connected to the read semiconductor pattern, and a bit line on the substrate and extending lengthwise in the vertical direction and electrically connected to the read semiconductor pattern and the write semiconductor pattern.

According to some embodiments of the present disclosure, a semiconductor memory device includes a substrate, a protective insulating layer on the substrate, first to seventh insulating layers sequentially stacked on the protective insulating layer in a vertical direction perpendicular to an upper surface of the substrate, read word lines in the first insulating layer and spaced apart from each other in a first horizontal direction parallel to the upper surface of the substrate, wherein each of the read word lines extends lengthwise in a second horizontal direction parallel to the upper surface of the substrate and intersecting the first horizontal direction, read semiconductor patterns in the third insulating layer and spaced apart from each other in the second horizontal direction, wherein each of the read semiconductor patterns extends lengthwise in the first horizontal direction and overlaps a corresponding read word line in the vertical direction, write semiconductor patterns in the fourth insulating layer and spaced apart from each other in the second horizontal direction, wherein each of the write semiconductor patterns extends lengthwise in the first horizontal direction, write word lines in the sixth insulating layer and spaced apart from each other in the first horizontal direction, wherein each of the write word lines extends lengthwise in the second horizontal direction, and overlaps a corresponding write semiconductor pattern in the vertical direction, a ground line extending through the first to seventh insulating layers and the read semiconductor pattern, and bit lines extending through the first to third insulating layers, a corresponding one of the read semiconductor patterns, a corresponding one of the second semiconductor patterns, and the fifth to seventh insulating layers.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is an example circuit diagram of a memory cell of a semiconductor memory device according to some embodiments;

FIGS. 2 to 44 are diagrams illustrating intermediate structures corresponding to intermediate steps of a method for manufacturing a semiconductor memory device according to some embodiments;

FIGS. 45 to 46 are diagrams illustrating a semiconductor memory device according to some embodiments; and

FIG. 47 is a diagram illustrating a semiconductor memory device according to some embodiments.

### DETAILED DESCRIPTION

The present disclosure now will be described more fully hereinafter with reference to the accompanying drawings, in which various embodiments are shown. It should also be emphasized that the disclosure provides details of alternative examples, but such listing of alternatives is not exhaustive. Furthermore, any consistency of detail between various examples should not be interpreted as requiring such detail. Additionally, items described in the singular herein may be provided in plural, as can be seen, for example, in the drawings. Thus, the description of a single item that is provided in plural should be understood to be applicable to the remaining plurality of items unless context indicates otherwise.

Although ordinal labels such as the first, second, and the like are used herein to describe various elements or components, these elements or components are not limited by these terms. These terms are merely used to distinguish one element or component from another element or component. Accordingly, terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In the following description, elements may be connected physically and/or electrically connected. As used herein, components described as being “electrically connected” are configured such that an electrical signal can be conducted from one component to the other (although such electrical signal may be attenuated in strength as it is conducted and may be selectively transferred).

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

An item, layer, or portion of an item or layer described as extending “lengthwise” in a particular direction has a length in the particular direction and a width perpendicular to that direction, where the length is greater than the width.

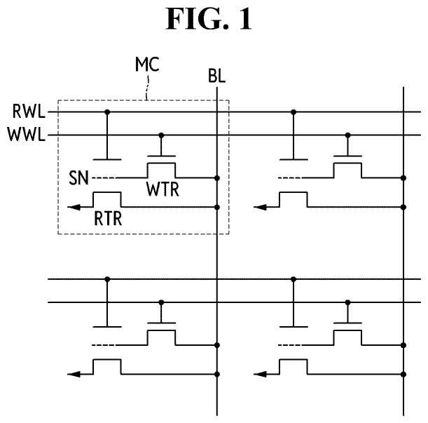

FIG. 1 is an example circuit diagram of a memory cell of a semiconductor memory device (e.g., a semiconductor chip) according to some embodiments.

Referring to FIG. 1, the semiconductor memory device according to some embodiments may include a plurality of memory cells MC. The memory cell MC may include a write transistor WTR and a read transistor RTR. The memory cells MC may be two-dimensionally or three-dimensionally arranged.

The write transistor WTR may be connected to and disposed between a storage node SN and a bit line BL. A gate terminal of the write transistor WTR may be connected to a write word line WWL, a first source/drain terminal of the write transistor WTR may be connected to the storage node SN, and a second source/drain terminal of the write transistor WTR may be connected to the bit line BL.

The read transistor RTR may be connected to and disposed between a ground line and the bit line BL. The ground line may be connected to a ground of an internal power source. A gate terminal of the read transistor RTR may be connected to a read word line RWL, a first source/drain terminal of the read transistor RTR may be connected to the ground line, and a second source/drain terminal of the read transistor RTR may be connected to the bit line BL. The gate terminal of the read transistor RTR may be referred to as the storage node SN. The gate terminal of the read transistor RTR may be connected to the other end of the write transistor WTR. The read word line RWL and the write word line WWL may be connected to a row decoder that selected a word line to be activated based on a received row address. The bit line BL may be connected to a column decoder to select a bit line BL based on a received column address.

In one example, the write operation of the memory cell MC may be as follows. A voltage may be applied to the write word line WWL and the bit line BL, and thus the write transistor WTR may be turned on. As the write transistor WTR is turned on, an electrical signal (charge) may be transferred (charged) to the storage node SN. Accordingly, the electrical signal of the bit line BL may be stored in the storage node SN, and as a result, a threshold voltage of the read transistor RTR may vary.

In one example, the read operation of the memory cell MC may be as follows. The write transistor WTR may be turned off, and a voltage may be applied to the bit line BL. The electrical signal stored in the storage node SN may be read under a current flowing through the read transistor RTR.

The semiconductor device including the memory cell MC may also be referred to as a two transistor-zero capacitor (2T-0C) memory device. The semiconductor device according to some embodiments may not include a separate capacitor for storing charges therein. Accordingly, an area required for forming the capacitor is reduced, so that the semiconductor memory device may be highly integrated and a manufacturing cost thereof may be reduced.

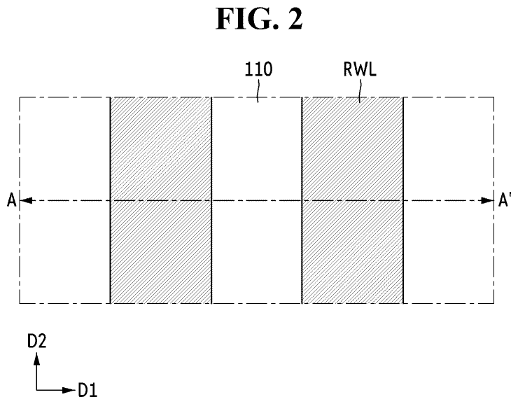

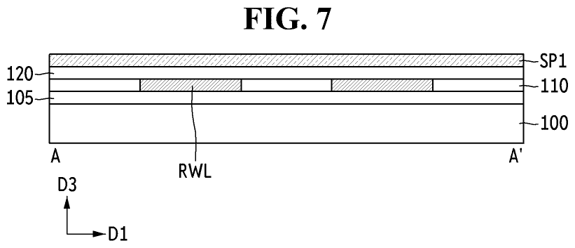

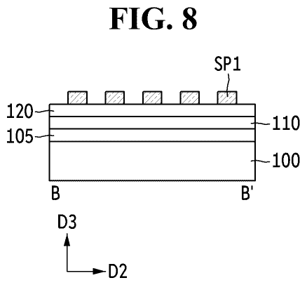

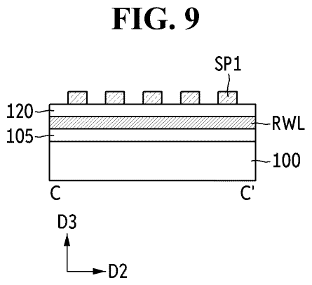

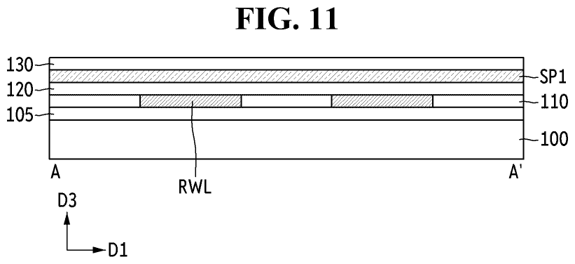

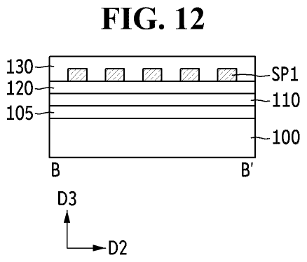

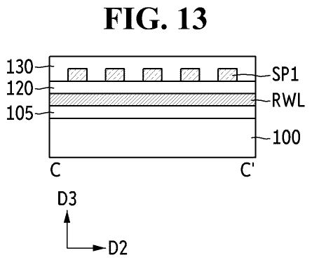

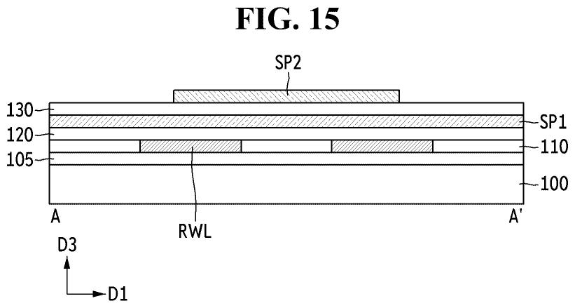

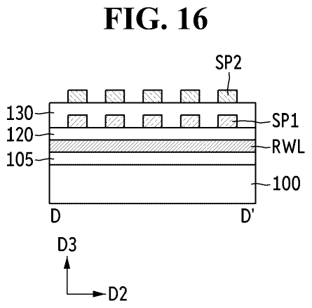

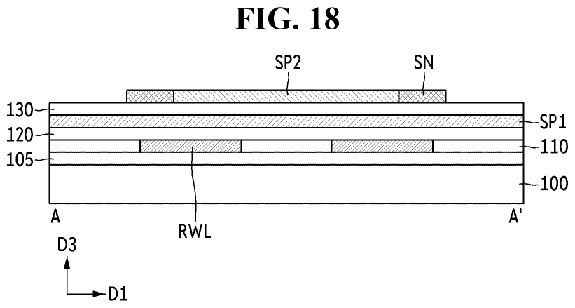

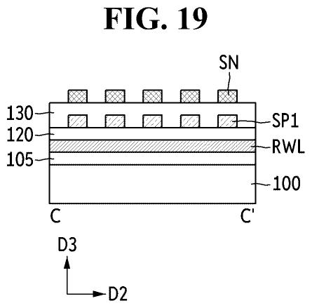

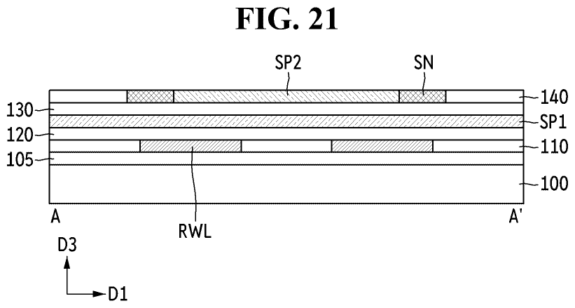

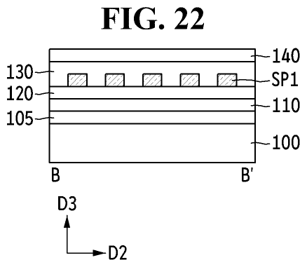

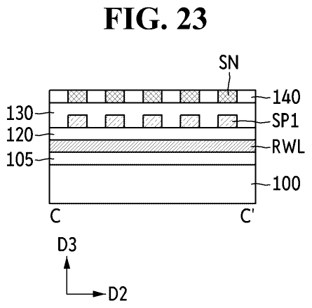

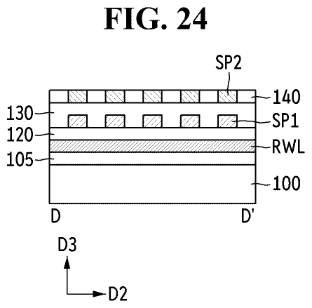

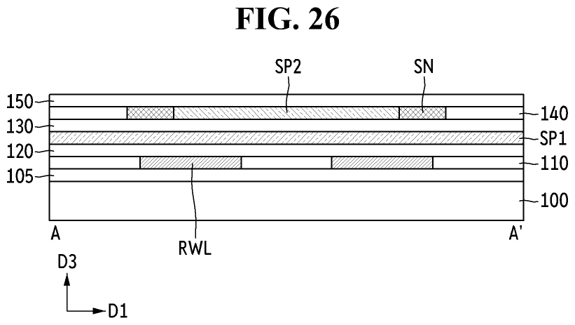

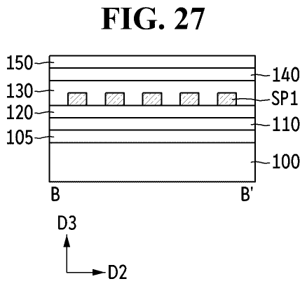

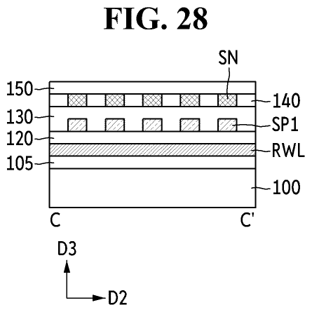

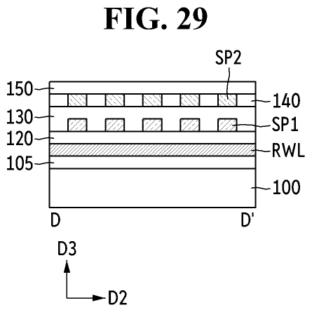

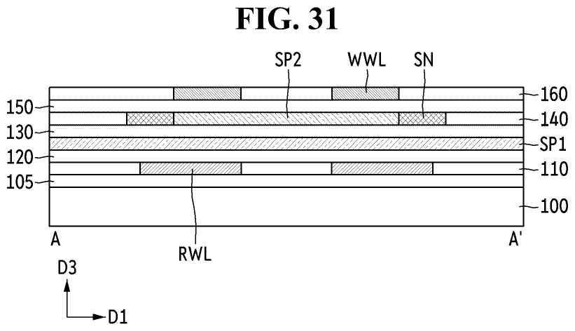

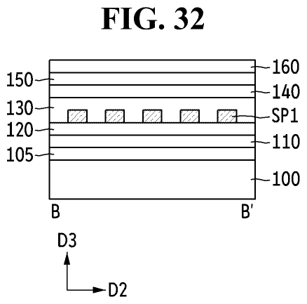

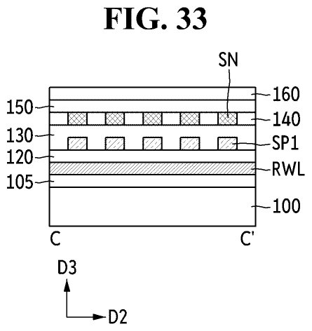

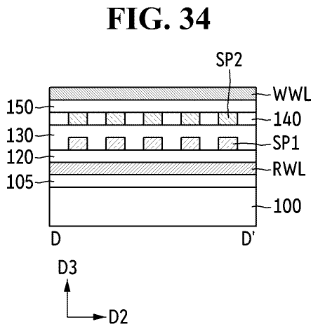

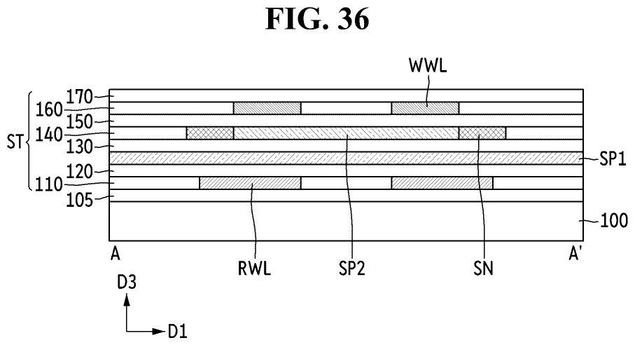

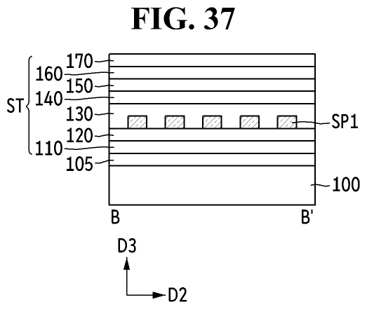

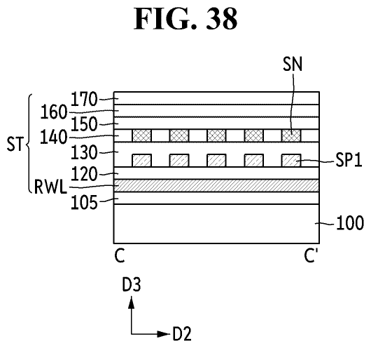

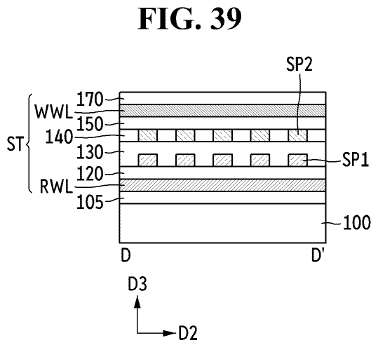

FIGS. 2 to 44 are diagrams illustrating intermediate structures corresponding to intermediate steps of a method for manufacturing a semiconductor memory device according to some embodiments.

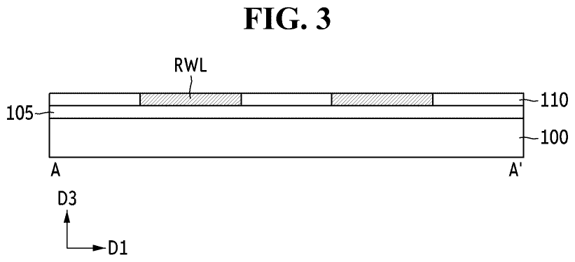

Referring to FIGS. 2 and 3, a protective insulating layer 105 may be formed on a substrate 100.

The substrate 100 may be a silicon substrate or a silicon-on-insulator (SOI) substrate. Alternatively, the substrate 100 may include silicon germanium, silicon germanium on insulator (SGOI), indium antimonide, lead telluride compound, indium arsenide, indium phosphide, gallium arsenide, or gallium antimonide. However, the inventive concept is not limited thereto.

The protective insulating layer 105 may be made of an insulating material. The protective insulating layer 105 may include, for example, silicon oxide, silicon oxynitride, a high-k insulating material having a higher dielectric constant than that of silicon oxide, or a combination thereof. The high-k insulating material may include a metal oxide or a metal oxynitride. For example, the high-k insulating material may include at least one of hafnium oxide, hafnium silicon oxide, hafnium silicon oxynitride, hafnium tantalum oxide, hafnium titanium oxide, hafnium zirconium oxide, zirconium oxide, aluminum oxide, or lanthanum oxide. However, the inventive concept is not limited thereto.

In the following description, the first direction D1, the second direction D2, and the third direction D3 may be directions that intersect each other. The third direction D3 may be perpendicular to an upper surface of the substrate 100, and the first direction D1 and the second direction D2 may be parallel to the upper surface of the substrate 100. The first direction D1 may be referred to as a first horizontal direction, the second direction D2 may be referred to as a second horizontal direction, and the third direction D3 may be referred to as a vertical direction.

Subsequently, a first insulating layer 110 and read word lines RWL may be formed on the protective insulating layer 105. The read word lines RWL may extend lengthwise in the second direction D2. The read word lines RWL may be spaced apart from each other in the first direction D1. The first insulating layer 110 may fill a space between the read word lines RWL. The first insulating layer 110 may be in contact with the read word lines RWL.

The read word lines RWL may each include a conductive material. The read word lines RWL may include, for example, at least one of a doped semiconductor material, a conductive metal nitride, a conductive metal silicon nitride, a metal carbonitride, a conductive metal silicide, a conductive metal oxide, a two-dimensional material, or a metal. Each of the read word lines RWL is illustrated as being embodied as a single film. However, the inventive concept is not limited thereto.

In the semiconductor device according to some embodiments, the two-dimensional material may be a metallic material and/or a semiconductor material. The two-dimensional material 2D material may include a two-dimensional allotrope or a two-dimensional compound, and may include, for example, one of graphene, molybdenum disulfide (MoS₂), molybdenum diselenide (MoSe₂), tungsten diselenide (WSe₂), tungsten disulfide (WS₂), or a combination thereof. However, the inventive concept is not limited thereto. The above-described two-dimensional material is only listed by way of example, the two-dimensional material that may be included in the semiconductor device of the inventive concept is not limited to the above-described material.

The first insulating layer 110 may fill a space between the read word lines RWL. The first insulating layer 110 may be formed on a portion of the protective insulating layer 105 on which the read word lines RWL are not formed.

The first insulating layer 110 may be made of an insulating material. The first insulating layer 110 may include, for example, silicon oxide, silicon oxynitride, the above-described high-k insulating material having a higher dielectric constant than that of silicon oxide, or a combination thereof.

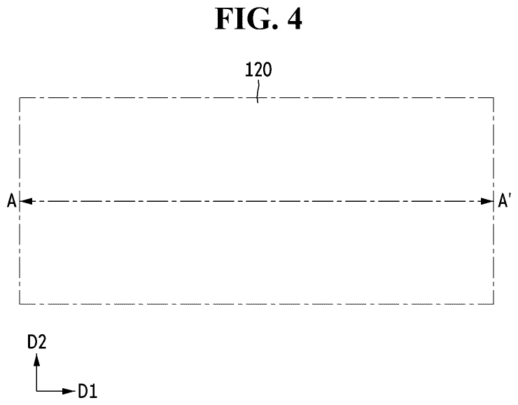

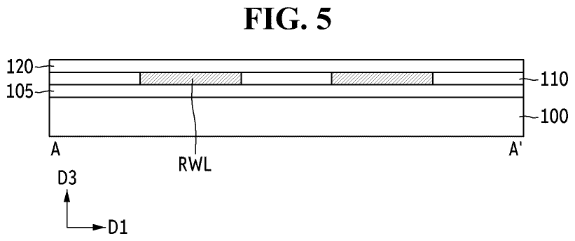

Referring to FIGS. 4 and 5, a second insulating layer 120 may be formed on the read word lines RWL and the first insulating layer 110. The second insulating layer 120 may be in contact with the read word lines RWL and the first insulating layer 110.

The second insulating layer 120 may be made of an insulating material. The second insulating layer 120 may include, for example, silicon oxide, silicon oxynitride, the above-described high-k insulating material having a higher dielectric constant than that of silicon oxide, or a combination thereof.

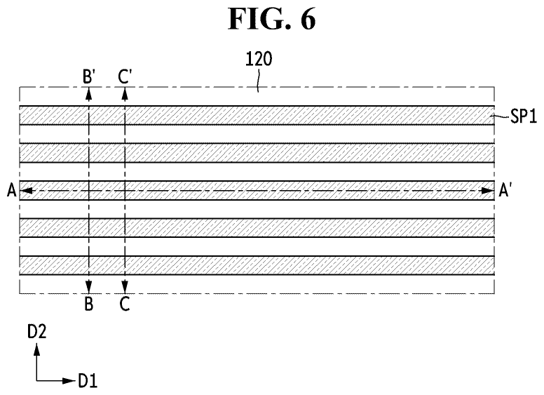

Referring to FIGS. 6 to 9, first semiconductor patterns SP1 may be formed on the second insulating layer 120. The first semiconductor patterns SP1 may extend in the first direction D1. The first semiconductor patterns SP1 may be spaced apart from each other in the second direction D2. At least a portion of the first semiconductor patterns SP1 may overlap the read word line RWL in the third direction D3. One read word line RWL may overlap a plurality of first semiconductor patterns SP1 spaced apart from each other in the second direction D2 in the third direction D3.

In some embodiments, the first semiconductor patterns SP1 may each include an oxide semiconductor material. The first semiconductor pattern SP1 may include, for example, a metal oxide. For example, the first semiconductor patterns SP1 may be an amorphous metal oxide film. In another example, the first semiconductor patterns SP1 may be a polycrystalline metal oxide film. In still another example, the first semiconductor patterns SP1 may include a combination of an amorphous metal oxide film and a polycrystalline metal oxide film. In still yet another example, the first semiconductor patterns SP1 may be a CAAC (c-axis aligned crystalline) metal oxide film.

The first semiconductor patterns SP1 may include, for example, one of indium oxide, tin oxide, zinc oxide, In-Zn-based oxide(IZO), Sn-Zn-based oxide, Al—Znbased oxide, Zn—Mg-based oxide, Sn—Mg-based oxide, In—Mg-based oxide, In—Ga-based oxide(IGO), In—Ga—Zn-based oxide(IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, or In—Hf—Al—Zn-based oxide. However, the inventive concept is not limited thereto.

In this regard, the In—Ga—Zn-based oxide refers to an oxide having In, Ga, and Zn as main components, but does not refer to a ratio of contents of In, Ga, and Zn. For example, when the In—Ga—Zn-based oxide is indium gallium zinc oxide (IGZO), the first semiconductor pattern SP1 may include IGZO (indium gallium zinc oxide, InₓGa_{y}Zn_{z}O). IGZO (In:Ga:Zn=1:1:1) including indium, gallium, and zinc at an equal content may be the In—Ga—Zn-based oxide. Ga-rich IGZO may have a higher gallium content than that in IGZO(In:Ga:Zn=1:1:1) and a lower indium content than that in IGZO(In:Ga:Zn=1:1:1). The Ga-rich IGZO may also be the In-Ga-Zn-based oxide. In addition, In-rich IGZO may have a higher indium content than that in IGZO(In:Ga:Zn=1:1:1) and a lower gallium content than that in IGZO(In:Ga:Zn=1: 1:1). The In-rich IGZO may also be the In-Ga-Zn-based oxide.

The above-described description has been made based on IGZO. However, the inventive concept is not limited thereto. When the first semiconductor patterns SP1 include a ternary or higher metal oxide, the above description may be equally applied thereto. In addition, when the first semiconductor patterns SP1 include the In—Ga—Zn-based oxide, the first semiconductor patterns SP1 may further contain a doped metal element other than In, Ga, and Zn.

In some embodiments, the first semiconductor patterns SP1 may include a semiconductor material which can be deposited. For example, the first semiconductor patterns SP1 may include one of silicon, silicon germanium, or polysilicon. However, the inventive concept is not limited thereto.

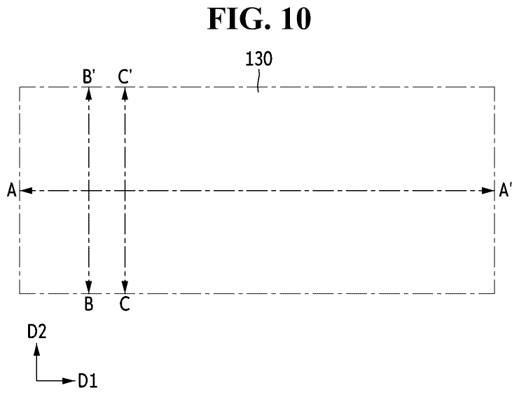

Referring to FIGS. 10 to 13, a third insulating layer 130 may be formed on the first semiconductor patterns SP1 and the second insulating layer 120. The third insulating layer 130 may fill a space between the first semiconductor patterns SP1. The third insulating layer 130 may cover the first semiconductor patterns SP1 and the second insulating layer 120. The third insulating layer 130 may be in contact with the first semiconductor patterns SP1 and the second insulating layer 120.

The third insulating layer 130 may be made of an insulating material. The third insulating layer 130 may include, for example, silicon oxide, silicon oxynitride, the above-described high-k insulating material having a higher dielectric constant than that of silicon oxide, or a combination thereof.

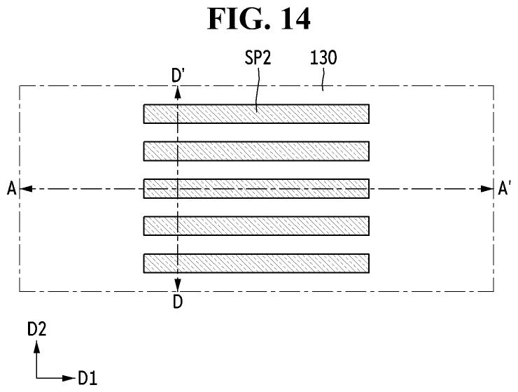

Referring to FIGS. 14 to 16, second semiconductor patterns SP2 may be formed on the third insulating layer 130. The second semiconductor patterns SP2 may each extend lengthwise in the first direction D1. The second semiconductor patterns SP2 may be spaced apart from each other in the second direction D2. At least a portion of each of the second semiconductor patterns SP2 may overlap at least a portion of a respective one of the first semiconductor patterns SP1 in the third direction D3. However, the inventive concept is not limited thereto. The second semiconductor patterns SP2 may be shorter in length than the first semiconductor patterns SP1 and may be referred to as write semiconductor patterns. Similarly, the first semiconductor patterns SP1 may be referred to as read semiconductor patterns.

In some embodiments, the second semiconductor patterns SP2 may include the oxide semiconductor material as described above.

In some embodiments, the second semiconductor patterns SP2 may include a semiconductor material capable of being deposited as described above.

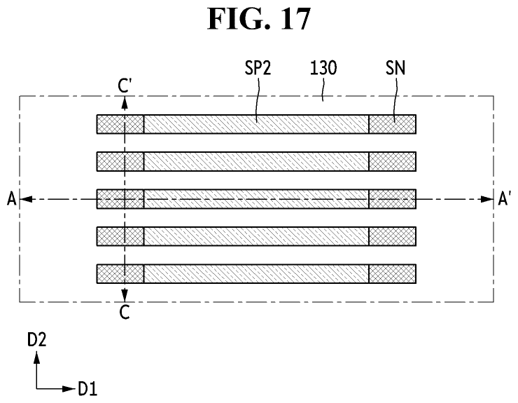

Referring to FIGS. 17 to 19, the storage nodes SN may be formed on the second semiconductor patterns SP2. For example, a storage node SN may be formed at each side of opposing ends in the first direction D1 of a second semiconductor pattern SP2. The storage nodes SN may be electrically connected to the second semiconductor pattern SP2. The storage node SN may be in contact with the second semiconductor pattern SP2. The storage node SN may overlap at least a portion of the first semiconductor pattern SP1 in the third direction D3.

In some embodiments, the storage node SN may include the same material as that of the second semiconductor pattern SP2.

In some embodiments, the storage node SN may include a conductive material. The storage node SN may include, for example, at least one of a doped semiconductor material, a conductive metal nitride, a conductive metal silicon nitride, a metal carbonitride, a conductive metal silicide, a conductive metal oxide, a two-dimensional material, or a metal. The storage node SN is illustrated as being embodied as a single film. However, the inventive concept is not limited thereto.

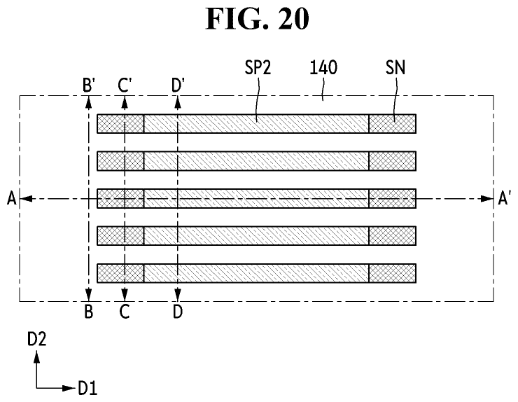

Referring to FIGS. 20 to 24, a fourth insulating layer 140 may be formed on the third insulating layer 130. The fourth insulating layer 140 may be formed on a portion of the third insulating layer 130 on which the second semiconductor pattern SP2 and the storage node SN are not formed. The fourth insulating layer 140 may fill a space between the second semiconductor patterns SP2. The fourth insulating layer 140 may be in contact with the second semiconductor pattern SP2, the storage node SN, and the third insulating layer 130.

The fourth insulating layer 140 may include an insulating material. The fourth insulating layer 140 may include, for example, silicon oxide, silicon oxynitride, the above-described high-k insulating material having a higher dielectric constant than that of silicon oxide, or a combination thereof.

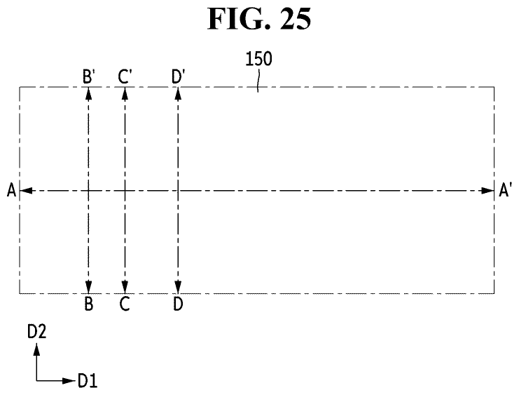

Referring to FIGS. 25 to 29, a fifth insulating layer 150 may be formed on the second semiconductor pattern SP2, the storage node SN, and the fourth insulating layer 140. The fifth insulating layer 150 may be in contact with the second semiconductor pattern SP2, the storage node SN, and the fourth insulating layer 140.

The fifth insulating layer 150 may include an insulating material. The fifth insulating layer 150 may include, for example, silicon oxide, silicon oxynitride, the above-described high-k insulating material having a higher dielectric constant than that of silicon oxide, or a combination thereof.

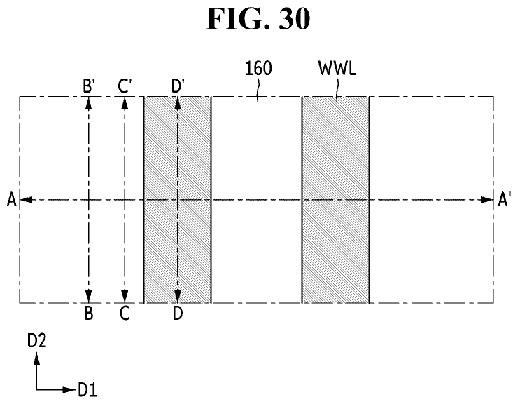

Referring to FIGS. 30 to 34, the write word line WWL and a sixth insulating layer 160 may be formed on the fifth insulating layer 150. The sixth insulating layer 160 may fill a space between the write word lines WWL. The sixth insulating layer 160 may be in contact with the write word line WWL and the fifth insulating layer 150.

The sixth insulating layer 160 may include an insulating material. The sixth insulating layer 160 may include, for example, silicon oxide, silicon oxynitride, the above-described high-k insulating material having a higher dielectric constant than that of silicon oxide, or a combination thereof.

The write word line WWL may extend in the second direction D2. The write word lines WWL may be spaced apart from each other in the first direction D1. At least a portion of the second semiconductor pattern SP2 may overlap the write word line WWL in the third direction D3. At least a portion of the write word line WWL may overlap the second semiconductor pattern SP2 in the third direction D3. However, the inventive concept is not limited thereto. One write word line WWL may overlap a plurality of second semiconductor patterns SP2 spaced apart from each other in the second direction D2 in the third direction D3.

A size relationship between a width of the read word line RWL in the first direction D1 and the width of the write word line WWL in the first direction D1 is not limited to that as illustrated. Unlike the illustrated example, the width of the read word line RWL in the first direction D1 may be smaller than or substantially equal to the width of the write word line WWL in the first direction D1.

The write word line WWL may include a conductive material. The write word line WWL may include, for example, at least one of a doped semiconductor material, a conductive metal nitride, a conductive metal silicon nitride, a metal carbonitride, a conductive metal silicide, a conductive metal oxide, a two-dimensional material, or a metal. The write word line WWL is illustrated as being embodied as a single film. However, the inventive concept is not limited thereto.

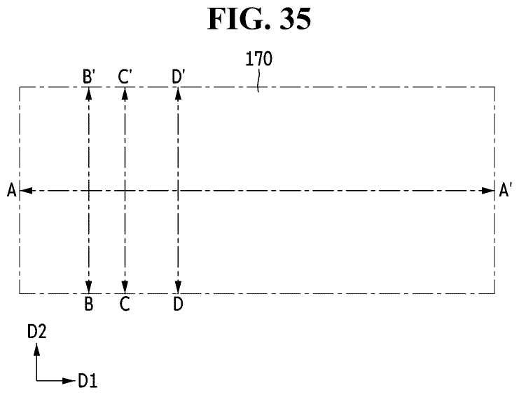

Referring to FIGS. 35 to 39, a seventh insulating layer 170 may be formed on the write word line WWL and the sixth insulating layer 160. The seventh insulating layer 170 may be in contact with the write word line WWL and the sixth insulating layer 160. At least a portion of the second semiconductor pattern SP2 may overlap the write word line WWL in the third direction D3. Accordingly, a stack structure ST including the first to seventh insulating layers 110, 120, 130, 140, 150, 160, and 170, the read word line RWL, the write word line WWL, the storage node SN, the first semiconductor pattern SP1, and the second semiconductor pattern SP2 may be formed.

The seventh insulating layer 170 may include an insulating material. The seventh insulating layer 170 may include, for example, silicon oxide, silicon oxynitride, the above-described high-k insulating material having a higher dielectric constant than that of silicon oxide, or a combination thereof. For example, the protective insulating layer 105, the second insulating layer 120, the third insulating layer 130, the fifth insulating layer 150, and the seventh insulating layer 170 may include the same material, while the first insulating layer 110, the fourth insulating layer 140, and the sixth insulating layer 160 may include the same material. However, the inventive concept is not limited thereto. For example, each of the first to seventh insulating layers 110, 120, 130, 140, 150, 160, and 170 may be a single film.

In the semiconductor memory device according to some embodiments, the read word line RWL, the first semiconductor pattern SP 1, the second semiconductor pattern SP2, the storage node SN, and the write word line WWL may be sequentially stacked in the third direction D3. For example, among the read word line RWL, the first semiconductor pattern SP1, the second semiconductor pattern SP2, the storage node SN, and the write word line WWL, the write word line WWL may be farthest from the substrate 100. The first to seventh insulating layers 110, 120, 130, 140, 150, 160, and 170 may be sequentially stacked in the third direction D3. The read word line RWL, the first semiconductor pattern SP1, the second semiconductor pattern SP2, the storage node SN, and the write word line WWL may be spaced apart from each other via the first to seventh insulating layers 110, 120, 130, 140, 150, 160, and 170.

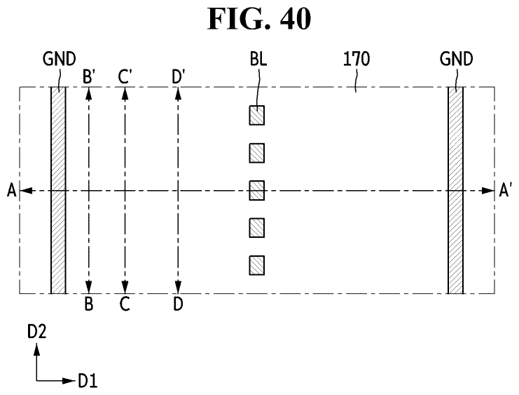

Referring to FIGS. 40 to 44, the stack structures ST may be repeatedly stacked in the third direction D3. The read word line RWL, the write word line WWL, the storage node SN, the first semiconductor pattern SP1, and the second semiconductor pattern SP2 may be repeatedly stacked in the third direction D3.

Subsequently, ground lines GND and bit lines BL may be formed on the substrate 100.

The ground lines GND may extend in the third direction D3 to extend through the stack structures ST and the protective insulating layer 105. The ground line GND may extend through the first to seventh insulating layers 110, 120, 130, 140, 150, 160, and 170 and the first semiconductor patterns SP1.

The ground line GND may be insulated from the read word line RWL via the first insulating layer 110. The ground line GND may be electrically connected to a first end E11 of the first semiconductor pattern SP1. The ground line GND may be in contact with the first end E11 of the first semiconductor pattern SP1. The ground line GND may be insulated from the storage node SN via the fourth insulating layer 140. The ground line GND may be insulated from the write word line WWL via the sixth insulating layer 160.

The first semiconductor patterns SP1 stacked in the third direction D3 may share the ground line GND. The first semiconductor patterns SP1 adjacent to each other in the first direction D1 while the ground line GND is interposed therebetween may share the ground line GND.

For example, the first to seventh insulating layers 110, 120, 130, 140, 150, 160, and 170 may be sequentially stacked on the protective insulating layer 105 in the third direction D3. The read word line RWL may be spaced apart from the first insulating layer 110 in the first direction D1 and may extend in the second direction D2. The first semiconductor pattern SP1 may extend in the first direction D1 and be disposed in the third insulating layer 130. The first semiconductor patterns SP1 may be spaced apart from each other in the second direction D2. A partition of the first semiconductor pattern SP1 may overlap the read word line RWL in the third direction D3. The second semiconductor pattern SP2 may extend in the first direction D1 and may be disposed in the fourth insulating layer 140. The second semiconductor patterns SP2 may be spaced apart from each other in the second direction D2. The write word line WWL may be disposed in the sixth insulating layer 160. The write word lines WWL may be spaced apart from each other in the first direction D1. The write word line WWL may extend in the second direction D2. The write word line WWL may overlap the second semiconductor pattern SP2 in the third direction D3. The ground line GND may extend through the first to seventh insulating layers 110, 120, 130, 140, 150, 160, and 170 and the first semiconductor pattern SP1. The bit line BL may extend through the first to third insulating layers 110, 120, and 130, the first semiconductor pattern SP1, the second semiconductor pattern SP2, and the fifth to seventh insulating layers 150, 160, and 170.

In some embodiments, the ground line GND may extend in the second direction D2. The first semiconductor patterns SP1 spaced apart from each other in the second direction D2 may share the ground line GND. In a plan view (e.g., a plane including the first direction D1 and the second direction D2), the ground line GND may have a bar shape extending in the second direction D2.

The ground lines GND may be spaced apart from each other in the first direction D1. Both opposing ground lines GND may be respectively disposed on both opposing sides in the first direction D1of the bit line BL. The bit line BL may be disposed between the ground lines GND adjacent to each other in the first direction D1.

The bit line BL may extend in the third direction D3 so as to extend through the stack structures ST and/or the protective insulating layer 105. The bit line BL may extend through the first to third insulating layers 110, 120, and 130, the first semiconductor pattern SP1, the second semiconductor pattern SP2, and the fifth to seventh insulating layers 150, 160, and 170.

The bit line BL may be insulated from the read word line RWL via the first insulating layer 110. The bit line BL may be electrically connected to a second end E12 of the first semiconductor pattern SP1. The bit line BL may be in contact with the second end E12 of the first semiconductor pattern SP1. The first end E11 and the second end E12 of the first semiconductor pattern SP1 may be opposite to each other in the first direction D1.

The bit line BL may be insulated from the write word line WWL via the sixth insulating layer 160. The bit line BL may be electrically connected to the second end E22 of the second semiconductor pattern SP2. The bit line BL may be in contact with the second end E22 of the second semiconductor pattern SP2. The first end E21 of the second semiconductor pattern SP2 may be electrically connected to the storage node SN. The first end E21 of the second semiconductor pattern SP2 may be in contact with the storage node SN. The first end E21 and the second end E22 of the second semiconductor pattern SP2 may be opposite to each other in the first direction D1.

The first semiconductor patterns SP1 and the second semiconductor patterns SP2 stacked in the third direction D3 may share the bit line BL. The first semiconductor patterns SP1 and the second semiconductor patterns SP2 adjacent to each other in the first direction D1 while the bit line BL is disposed therebetween may share the bit line BL.

The bit lines BL may be spaced apart from each other in the second direction D2 while the bit lines are interposed between the ground lines GND adjacent to each other in the first direction D1. The read word line RWL, the write word line WWL, the storage node SN, the first semiconductor pattern SP1, and the second semiconductor pattern SP2 may be disposed between the ground line GND and the bit line BL which are adjacent to each other in the first direction D1. The read word lines RWL which are respectively disposed on both opposing sides in the first direction D1 of the bit line BL may be mirror-symmetrical with each other around the bit line BL. The write word lines WWL which are respectively disposed on both opposing sides in the first direction D1 of the bit line BL may be mirror-symmetrical with each other around the bit line BL. The storage nodes SN which are respectively disposed on both opposing sides in the first direction D1 of the bit line BL may be mirror-symmetrical with each other around the bit line BL. The first semiconductor patterns SP1 which are respectively disposed on both opposing sides in the first direction D1 of the bit line BL may be mirror-symmetrical with each other around the bit line BL. The second semiconductor patterns SP2 which are respectively disposed on both opposing sides in the first direction D1 of the bit line BL may be mirror-symmetrical with each other around the bit line BL.

Each of the bit lines BL may be electrically connected to the first semiconductor patterns SP 1 which are spaced apart from each other in the second direction D2 and to the second semiconductor patterns SP2 which are spaced apart from each other in the second direction D2. For example, the first semiconductor patterns SP1 spaced apart from each other in the second direction D2 may be connected to different bit lines BL, respectively. The second semiconductor patterns SP2 spaced apart from each other in the second direction D2 may be connected to different bit lines BL, respectively.

In some embodiments, in a plan view (e.g., a plane including the first direction D1 and the second direction D2), the bit line BL may have a rectangular shape.

Each of the bit line BL and the ground line GND may include a conductive material. Each of the bit line BL and the ground line GND may include, for example, at least one of a doped semiconductor material, a conductive metal nitride, a conductive metal silicon nitride, a metal carbonitride, a conductive metal silicide, a conductive metal oxide, a two-dimensional material, or a metal. Although each of the bit line BL and the ground line GND is illustrated as being embodied as a single film, the inventive concept is not limited thereto.

Referring to FIGS. 1 to 44, a first portion including the first end E11 of the first semiconductor pattern SP1 may be used as a first source/drain terminal of the read transistor RTR, a second portion including the second end E12 of the first semiconductor pattern SP1 may be used as a second source/drain terminal of the read transistor RTR, and a third portion between the first portion and the second portion of the first semiconductor pattern SP1 may be used as a channel area of the read transistor RTR. A first portion including the first end E21 of the second semiconductor pattern SP2 may be used as a first source/drain terminal of the write transistor WTR, a second portion including the storage node SN and the second end E22 of the second semiconductor pattern SP2 may be used as a second source/drain terminal of the write transistor WTR, and a third portion between the first portion and the second portion of the second semiconductor pattern SP2 may be used as a channel area of the write transistor WTR. The first semiconductor patterns SP1 may be referred to as read semiconductor patterns and the second semiconductor patterns SP2 may be referred to as write semiconductor patterns.

Each of the read transistor RTR and the write transistor WTR may be a horizontal channel transistor in which a channel area extends in a direction (e.g., the first direction D1) parallel to the upper surface of the substrate 100.

The read transistor RTR and the write transistor WTR may be of the same conductivity type. For example, each of the read transistor RTR and the write transistor WTR may be a NMOS transistor. In this case, each of the first semiconductor pattern SP1 and the second semiconductor pattern SP2 may include the oxide semiconductor material as described above.

In another example, each of the read transistor RTR and the write transistor WTR may be a PMOS transistor. In this case, each of the first semiconductor pattern SP 1 and the second semiconductor pattern SP2 may include the above-described semiconductor material capable of being deposited.

In the semiconductor memory device according to some embodiments, each of the read transistor RTR and the write transistor WTR may be configured as a planar transistor. Accordingly, the difficulty in the manufacturing process of the semiconductor memory device may be improved and/or reduced.

In the semiconductor memory device according to some embodiments, the memory cells MC, each including the read transistor RTR and the write transistor WTR, may be arranged in the first to third directions D1, D2, and D3. Accordingly, the integration of the semiconductor memory device may be improved and/or increased.

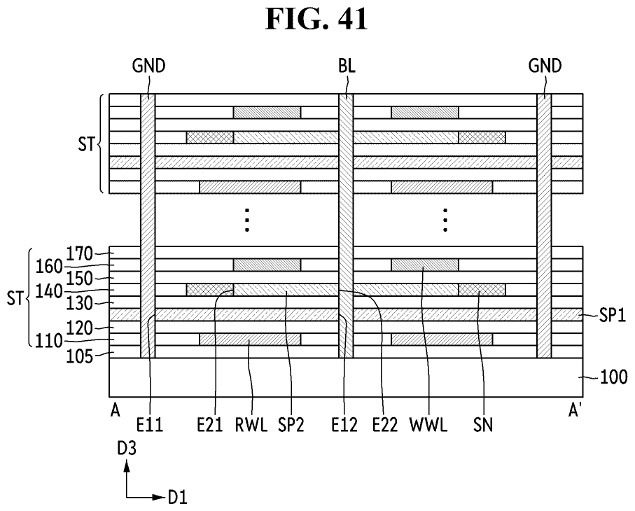

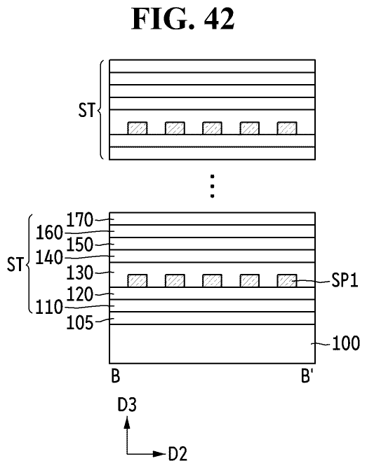

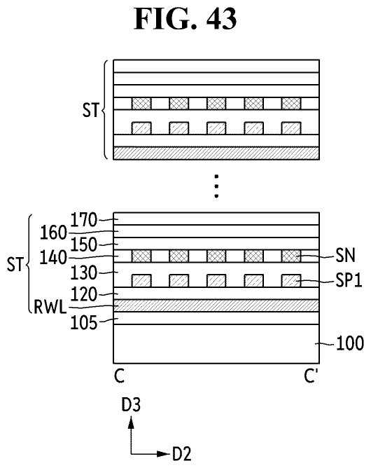

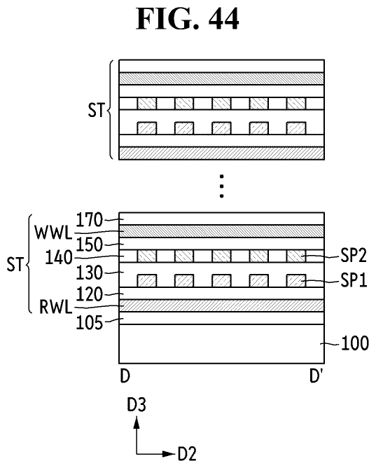

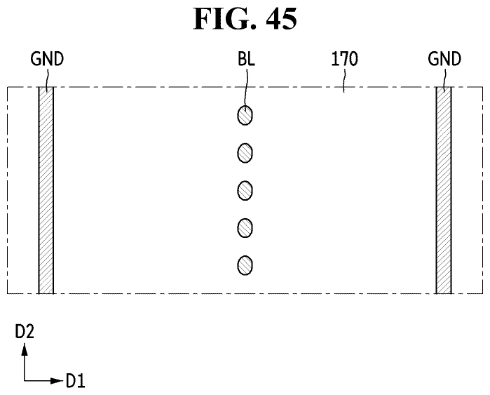

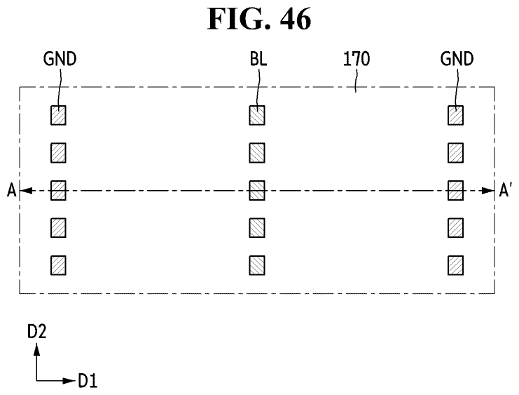

FIGS. 45 to 46 are example diagrams for illustrating a semiconductor memory device according to some embodiments. For convenience of description, differences thereof from those as described above with reference to FIGS. 1 to 44 will be mainly described and description of components that would be duplicative may be omitted with the understanding that the previous description is applicable. A cross-sectional view taken along a line A-A′ of FIGS. 45 and 46 is FIG. 41, a cross-sectional view taken along a line B-B′ of FIGS. 45 and 46 is FIG. 42, a cross-sectional view taken along a line C-C′ of FIGS. 45 and 46 is FIG. 43, and a cross-sectional view taken along a line D-D′ of FIGS. 45 and 46 is FIG. 44.

Referring to FIG. 45, in the semiconductor memory device according to some embodiments, the bit line BL may have a circular or elliptical shape in a plan view (e.g., a plane including the first direction D1 and the second direction D2).

Referring to FIG. 46, in the semiconductor memory device according to some embodiments, the ground lines GND may be spaced apart from each other in the second direction D2. The first semiconductor patterns SP1 spaced apart from each other in the second direction D2 may be electrically connected to the ground lines GND, respectively. For example, the first semiconductor patterns SP1 spaced apart from each other in the second direction D2 may be connected to different ground lines GND, respectively.

The ground line GND and the bit line BL may be spaced apart from each other in the first direction D1.

In some embodiments, in a plan view (e.g., a plane including the first direction D1 and the second direction D2), the bit line BL may have a rectangular shape.

In some embodiments, the ground line GND may have a circular or elliptical shape in a plan view (e.g., a plane including the first direction D1 and the second direction D2).

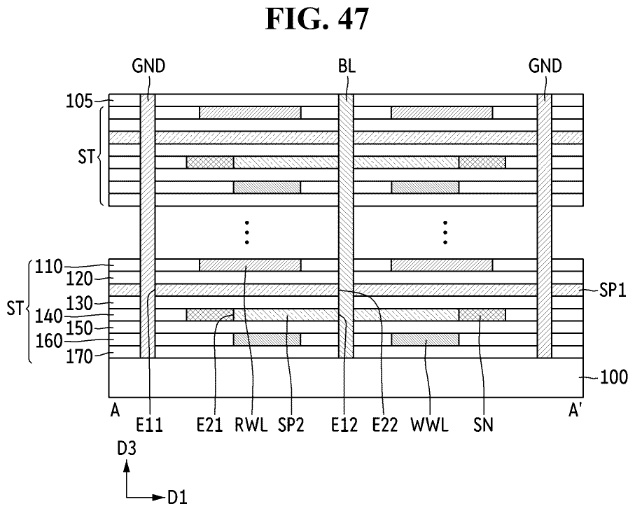

FIG. 47 is an example diagram illustrating a semiconductor memory device according to some embodiments. For convenience of description, differences thereof from those as described above with reference to FIGS. 1 to 46 will be mainly described and description of components that would be duplicative may be omitted with the understanding that the previous description is applicable. FIG. 47 is a cross-sectional view taken along a line A-A′ of FIGS. 40, 45, or 46.

Referring to FIG. 47, in the semiconductor memory device according to some embodiments, the write word line WWL, the second semiconductor pattern SP2, the storage node SN, the first semiconductor pattern SP1, and the read word line RWL may be sequentially stacked in the third direction D3. The first to seventh insulating layers 110, 120, 130, 140, 150, 160, and 170 may be sequentially stacked in a direction opposite to the third direction D3. For example, the write word line WWL among the write word line WWL, the second semiconductor pattern SP2, the storage node SN, the first semiconductor pattern SP1, and the read word line RWL may be closest to the substrate 100. For example, the first semiconductor pattern SP1 (e.g., long semiconductor pattern or read semiconductor pattern) may be at a higher level relative to the substrate 100 than the second semiconductor pattern SP2 (e.g., short semiconductor pattern or write semiconductor pattern).

The seventh insulating layer 170, the write word line WWL, the sixth insulating layer 160, the fifth insulating layer 150, the storage node SN, the second semiconductor pattern SP2, the fourth insulating layer 140, the first semiconductor pattern SP 1, the third insulating layer 130, the second insulating layer 120, the read word line RWL, and the first insulating layer 110 may be sequentially formed on the substrate 100. The protective insulating layer 105 may be formed on the uppermost stack structure ST.

Although embodiments of the present disclosure have been described above with reference to the accompanying drawings, the inventive concept is not limited to the described embodiments and may be implemented in various different forms. Those of ordinary skill in the technical field to which the present disclosure belongs will be able to appreciate that the inventive concept may be implemented in other specific forms without changing the technical idea or features of the inventive concept. Therefore, it should be understood that embodiments as described above are not restrictive but illustrative in all respects.

What is claimed is:

1. A semiconductor memory device comprising:
a substrate;
a ground line on the substrate and extending in a vertical direction perpendicular to an upper surface of the substrate;
a bit line on the substrate and spaced apart from the ground line in a first horizontal direction parallel to the upper surface of the substrate, wherein the bit line extends lengthwise in the vertical direction; and
a read word line, a read semiconductor pattern, a write semiconductor pattern, and a write word line between the ground line and the bit line and sequentially spaced apart from each other in the vertical direction,
wherein a first end of the read semiconductor pattern in the first horizontal direction is electrically connected to the bit line and a second end opposite the first end of the read semiconductor pattern is electrically connected to the ground line,
wherein an end of the write semiconductor pattern in the first horizontal direction is electrically connected to the bit line.

2. The semiconductor memory device of claim 1, wherein each of the read semiconductor pattern and the write semiconductor pattern includes an oxide semiconductor material.

3. The semiconductor memory device of claim 1, wherein each of the read word line and the write word line extends lengthwise in a second horizontal direction parallel to the upper surface of the substrate and intersecting the first horizontal direction,
wherein the read word line overlaps with the read semiconductor pattern in the vertical direction,
wherein the write word line overlaps the write semiconductor pattern in the vertical direction.

4. The semiconductor memory device of claim 1, further comprising:
a first insulating layer between the ground line and the read word line, and between the read word line and the bit line; and
a second insulating layer disposed between the ground line and the write word line and between the write word line and the bit line,
wherein each of the first insulating layer and the second insulating layer is a single film.

5. The semiconductor memory device of claim 1, wherein the ground line is a first ground line of a plurality of ground lines, the read word line is a first read word line of a plurality of read word lines, the read semiconductor pattern is a first read semiconductor pattern of a plurality of read semiconductor patterns, the write word line is a first write word line of a plurality of write word lines, and the write semiconductor pattern is a first write semiconductor pattern of a plurality of write semiconductor patterns, the semiconductor memory device further comprising a second ground line, a second read word line, a second read semiconductor pattern, a second write word line, and a second write semiconductor pattern, wherein the first ground line is disposed on a first side of the bit line and the second ground line is disposed on an opposite side of the bit line in the first horizontal direction of the bit line,
wherein each of the second read word line, the second read semiconductor pattern, the second write semiconductor pattern, and the second write word line is disposed between the second ground line and the bit line.

6. The semiconductor memory device of claim 5, wherein the first read word line and the second read word line are arranged symmetrically with respect to the bit line,
wherein the first read semiconductor pattern and the second read semiconductor pattern are arranged symmetrically with respect to the bit line,
wherein the first write semiconductor pattern and the second write semiconductor pattern are arranged symmetrically with respect to the bit line,
wherein the first write word line and the second write word line are arranged symmetrically with respect to the bit line.

7. The semiconductor memory device of claim 1, wherein the read semiconductor pattern is one of a plurality of read semiconductor patterns, and the write semiconductor pattern is one of a plurality of write semiconductor patterns,
wherein each of the read semiconductor patterns and each of the write semiconductor patterns extend in the first horizontal direction,
wherein the read semiconductor patterns are spaced apart from each other in a second horizontal direction parallel to the upper surface of the substrate and intersecting the first horizontal direction,
wherein the write semiconductor patterns are spaced apart from each other in the second horizontal direction,
wherein each of the read word line and the write word line extends lengthwise in the second horizontal direction.

8. The semiconductor memory device of claim 7, wherein the bit line is one of a plurality of bit lines and the bit lines are spaced apart from each other in the second horizontal direction,
wherein each of the write semiconductor patterns is electrically connected to a corresponding bit line of the plurality of bit lines.

9. The semiconductor memory device of claim 7, wherein the read semiconductor patterns spaced apart from each other in the second horizontal direction share the ground line with each other.

10. The semiconductor memory device of claim 7, wherein the ground line includes a plurality of ground lines spaced apart from each other in the second horizontal direction, wherein each of the read semiconductor patterns is connected to a corresponding one of the ground lines.

11. The semiconductor memory device of claim 1, wherein the read word line, the read semiconductor pattern, the write semiconductor pattern, and the write word line constitute a stack, wherein the stack is repeated in the vertical direction.

12. The semiconductor memory device of claim 1, further comprising a storage node electrically connected to the write semiconductor pattern,
wherein the storage node and the write semiconductor pattern consist of the same material.

13. The semiconductor memory device of claim 1, further comprising a storage node electrically connected to the write semiconductor pattern,
wherein the storage node includes a conductive material.

14. A semiconductor memory device comprising:
a substrate;
a read semiconductor pattern on the substrate and extending lengthwise in a first horizontal direction parallel to an upper surface of the substrate;
a read word line between the substrate and the read semiconductor pattern and extending lengthwise in a second horizontal direction parallel to the upper surface of the substrate and intersecting the first horizontal direction;
a write semiconductor pattern on the read semiconductor pattern and extending lengthwise in the first horizontal direction;
a write word line on the write semiconductor pattern and extending lengthwise in the second horizontal direction;
a ground line on the substrate, extending in a vertical direction perpendicular to the upper surface of the substrate and electrically connected to the read semiconductor pattern; and
a bit line on the substrate and extending lengthwise in the vertical direction and electrically connected to the read semiconductor pattern and the write semiconductor pattern.

15. The semiconductor memory device of claim 14, wherein the read semiconductor pattern is one of a plurality of read semiconductor patterns and the read semiconductor patterns are spaced apart from each other in the second horizontal direction,
wherein the write semiconductor pattern is one of a plurality of write semiconductor patterns and the write semiconductor patterns are spaced apart from each other in the second horizontal direction,
wherein the read word line overlaps with the plurality of read semiconductor patterns in the vertical direction,
wherein the write word line overlaps the plurality of write semiconductor patterns in the vertical direction.

16. The semiconductor memory device of claim 15, further comprising:
a first insulating layer between the read word line and the read semiconductor patterns and between the read semiconductor patterns adjacent to each other in the second horizontal direction; and
a second insulating layer between the ground line and the write semiconductor pattern and between the write semiconductor patterns adjacent to each other in the second horizontal direction.

17. The semiconductor memory device of claim 16, wherein each of the first insulating layer and the second insulating layer is a single film.

18. The semiconductor memory device of claim 14, wherein the write semiconductor pattern overlaps the read semiconductor pattern in the vertical direction.

19. A semiconductor memory device comprising:
a substrate;
a protective insulating layer on the substrate;
first to seventh insulating layers sequentially stacked on the protective insulating layer in a vertical direction perpendicular to an upper surface of the substrate;
read word lines in the first insulating layer and spaced apart from each other in a first horizontal direction parallel to the upper surface of the substrate, wherein each of the read word lines extends lengthwise in a second horizontal direction parallel to the upper surface of the substrate and intersecting the first horizontal direction;
read semiconductor patterns in the third insulating layer and spaced apart from each other in the second horizontal direction, wherein each of the read semiconductor patterns extends lengthwise in the first horizontal direction and overlaps a corresponding read word line in the vertical direction;
write semiconductor patterns in the fourth insulating layer and spaced apart from each other in the second horizontal direction, wherein each of the write semiconductor patterns extends lengthwise in the first horizontal direction;
write word lines in the sixth insulating layer and spaced apart from each other in the first horizontal direction, wherein each of the write word lines extends lengthwise in the second horizontal direction, and overlaps a corresponding write semiconductor pattern in the vertical direction;
a ground line extending through the first to seventh insulating layers and the read semiconductor pattern; and
bit lines with each bit line extending through the first to third insulating layers, a corresponding one of the read semiconductor patterns, a corresponding one of the write semiconductor patterns, and the fifth to seventh insulating layers.

20. The semiconductor memory device of claim 19, wherein the ground line extends in the second horizontal direction,
wherein the bit lines spaced apart from each other in the second horizontal direction.
